(19) United States
(12) Patent Application Publication
(10) Pub. No.: US 2010/0124613 A1
(43) Pub. Date: May 20, 2010

(54) Heater integrated thermocouple

(76) Inventor: Remco Van Den Berg, Emmeloord (NL)

Correspondence Address: LESTER H. BIRNBAUM, 6 OAKMOUNT COURT, SIMPSONVILLE, SC, 29681, US

(21) Appl. No.: 12/313,480

(22) Filed: Nov. 19, 2008

(51) Int. Cl. C23C 16/448; B05C 11/00; B05D 3/02

(52) U.S. Cl. 427/372.2; 118/722; 118/712

(57) ABSTRACT

The present invention discloses a system and method for relieving stresses from a layer deposited on the surface of a functional element used inside a reaction chamber. The system includes a heater which is integrated with the functional element. The heater heats the functional element to a temperature above the wafer processing temperature and independent of the wafer processing temperature in the reaction chamber. The independent heating of the reaction chamber causes cracking of the deposited layer. This relieves the stresses that are developed in the deposited layer and consequently, the functional element is safeguarded from failure.

### BACKGROUND

The present invention relates, in general, to the field of wafer processing in the semiconductor industry. More specifically, the present invention relates to the field of thermocouples for use in a reaction chamber of thermal film deposition reactors, in particular to thermocouples for use in Low Pressure Chemical Vapor Deposition (LPCVD) furnaces in semiconductor processing.

During the deposition process, unwanted films and particulate materials accumulate on surfaces other than the target substrate such as on functional elements. The functional elements may include a thermocouple, a quartz gas injector and the like. Unwanted layers keep depositing onto the surfaces of the functional elements during the deposition process, and due to stresses in the deposited layers, the functional elements may breakdown, resulting in improper functioning of the thermal film deposition reactor. This may result in an abort of the deposition process and increase downtime of the thermal film deposition reactor.

There are methods used for preventing the breakdown of the functional elements due to stresses in the deposited films. One of the existing methods involves wrapping silicon carbide sheets around the thermocouple to safeguard it from the deposition of the layers. However, this method is incompatible with NF₃ and CLF₃ cleaning. Another method adopted is to increase the thickness of the quartz sheath of the thermocouple and thereby increase the lifetime of the thermocouple. However, experiments with increased quartz sheath thickness have shown little or no success in preventing the thermocouple from breaking down.

Another approach to prevent breakdown of the functional elements is to reduce the stresses developed in the deposited layers. The method employs cooling and/or heating of the entire reaction chamber when the thickness of the deposited layers reaches a predetermined value. The deposited layers crack by alternate cooling and/or heating due to differences in coefficient of thermal expansion between the deposited layer and the functional elements of the reaction chamber. The cracking of the deposited layers relieves the stresses and avoids flake off of the deposited layer. The predetermined thickness is chosen small enough so that the deposited film cracks in a controlled manner without causing significant damage. However, this method involves heating and/or cooling of the entire reaction chamber and therefore there is a high risk of breakdown of other fragile parts in the reaction chamber.

Accordingly, there is a need for a system and method that can reduce the downtime of thermal film deposition reactors. The method and system preferably should crack the deposited layers on functional elements in a controlled manner to relieve the stresses. Further, the method and system preferably should be able to increase the lifetime of functional elements without heating and/or cooling of the entire reaction chamber.

### SUMMARY

An object of the present invention is to provide a system and method for efficient processing of one or more wafers inside a reaction chamber of a thermal film deposition apparatus.

Another object of the present invention is to provide a system and method for preventing flake off of a layer deposited on a functional element inside the reaction chamber.

Yet another objective of the present invention is to provide a system and method for heating the functional elements inside the reaction chamber independently.

Still another object of the present invention is to provide a system and method for cracking the layer deposited on the functional element inside the reaction chamber in a controlled way to relieve the stresses.

To achieve the objects mentioned above, the present invention provides a system and a method that includes heating of the functional elements independently of the reaction chamber. The functional element of the present invention when integrated with a heater forms a component for use inside a reaction chamber of a thermal film deposition apparatus. The functional element is integrated with a heater for heating the functional element independently of the reaction chamber when the thickness of deposited layers on the functional element reaches a predetermined cumulative film thickness. The functional elements of the present invention are not intended to include the reaction chamber walls or the reaction chamber elements like wafers which are processed inside the reaction chamber and do not perform any function inside the reaction chamber. In various embodiments of the present invention, the functional element may be a thermocouple, a quartz gas injector and the like. Further, the functional element is heated to a predefined temperature wherein the predefined temperature is determined based on the dimensions and material of functional element, and the material of the layer deposited on the surface of the functional element.

### BRIEF DESCRIPTION OF THE DRAWINGS

Various embodiments of the present invention will hereinafter be described in conjunction with the appended drawings, provided to illustrate and not to limit the present invention, wherein like designations denote like elements, and in which:

FIG. 1 is a schematic cross sectional diagram of a reaction chamber of a thermal film deposition apparatus in which the present invention may be practiced;

FIG. 2 is a top cross-sectional view of a paddle thermocouple in accordance with an embodiment of the present invention;

FIG. 3a is a cross-sectional view of the paddle thermocouple taken along line A-A′ of FIG. 2 in accordance with an embodiment of the present invention;

FIG. 3b is a perspective view of a ceramic tube in accordance with an embodiment of the present invention; and

FIG. 4 is a flowchart describing a method for processing semiconductor wafers in accordance with an embodiment of the present invention.

### DETAILED DESCRIPTION OF THE INVENTION

The present invention describes a system and a method for efficient processing of one or more wafers inside a reaction chamber of a thermal film deposition apparatus.

The present invention increases lifetime of the functional elements which are exposed to film deposition processing conditions by relieving stresses in the deposited layers. This results in preventing breakdown of the functional elements. During the deposition process, unwanted layers keep on depositing on the surfaces of the functional elements. As the deposition keeps on increasing on the surfaces of the functional elements, stresses are developed and may result in breakdown of the functional elements. The present invention involves integrating the functional element with a heater to form a component for use inside a reaction chamber of a thermal film deposition apparatus. The functional element performs specific functions inside a reaction chamber of the thermal film deposition apparatus such as measuring temperature conditions, passing process gas and the like. Examples of functional elements may include a thermocouple, a quartz gas injector and the like. The functional elements of the present invention are not intended to include the reaction chamber walls or the reaction chamber elements like wafers which are processed inside the reaction chamber and do not perform any function inside the reaction chamber. The heater heats the functional element to a predefined temperature independently of the reaction chamber when the deposited layers achieve a predetermined thickness. The alternate heating and cooling of the functional element develops cracks in the deposited layers which relieve the stresses and therefore prevent the breakdown of the functional element.

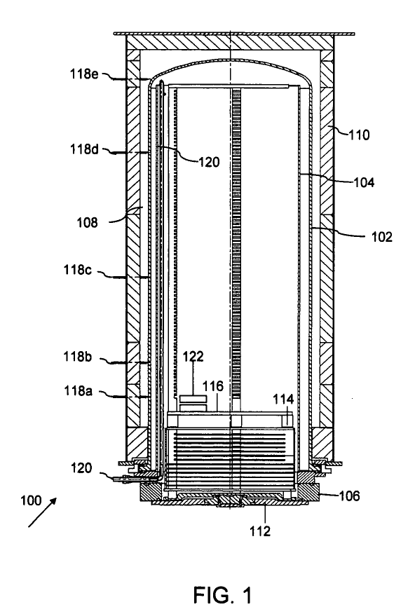

FIG. 1 is a cross-sectional schematic diagram of a reaction chamber of a thermal film deposition apparatus in which the present invention may be practiced. Reaction chamber 100 includes a process tube 102, an inner tube 104, flanges 106, a heating element 108 comprising a first heater (not shown) and an isolation mantle 110 surrounding the first heater, a door 112, a pedestal 114, a boat 116, spike thermocouples 118a, 118b, 118c, 118d and 118e, a paddle thermocouple 120 and a plurality of substrates 122. Thermocouples 118a, 118b, 118c, 118d and 118e are hereinafter referred to as spike thermocouples 118.

Process tube 102 and inner tube 104 rest on flanges 106. The assembly of process tube 102 and inner tube 104 is placed inside heating element 108. The outer surface of heating element 108 is covered with isolation mantle 110. The first heater (not shown) is provided in the space between process tube 102 and isolation mantle 110. The lower end of reaction chamber 100 is provided with door 112 on which pedestal 114 is supported. Boat 116 is supported on the upper surface of pedestal 114 for accommodating a plurality of substrates 122 in a horizontal position. The plurality of substrates 122 are arranged in a vertically spaced manner.

Spike thermocouples 118 and paddle thermocouple 120 are used to measure the temperature. Spike thermocouples 118 measure the temperature at the outside of process tube 102 in their respective heating zones. Paddle thermocouple 120 is positioned inside the process tube for measuring the temperature inside the process tube during the processing of substrates 122.

Hot gases are passed inside reaction chamber 100 for the deposition of a film on the semiconductor wafers. The temperature of reaction chamber 100 is maintained at a desired wafer processing temperature by using the first heater. The hot gases deposit on the semiconductor wafers, decompose and form a solid film. However, the hot gases are also deposited on paddle thermocouple 120, present inside reaction chamber 100. The hot gases decompose and form a layer on paddle thermocouple 120. The layer formed on paddle thermocouple 120 keeps on increasing in thickness during the deposition process and stresses are developed in the deposited layer. The intensity of the stresses increases with increasing thickness of the deposited layer. The intensity of stresses varies with the materials of the deposited layers. The intensity of stresses is higher in the case of polysilicon and silicon nitride layers than other layers, and therefore, makes paddle thermocouple 120 more susceptible to failure when used in such process chambers.

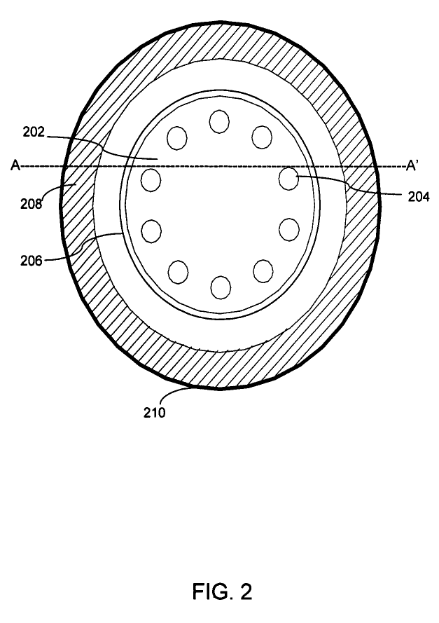

The thickness of the layer deposited on paddle thermocouple 120 can easily be derived from the cumulative thickness deposited on semiconductor wafers in consecutive runs. In accordance with various embodiments of the present invention, paddle thermocouple 120 is integrated with a second heater, described in FIG. 2, to heat paddle thermocouple 120 to a predefined temperature independently of the reaction chamber 100 when the deposited layers achieve a predetermined thickness.

The second heater heats paddle thermocouple 120 cyclically to a temperature above the wafer processing temperature. The temperature of reaction chamber 100 is maintained equal to or below the wafer processing temperature during heating of paddle thermocouple 120. The second heater is fired using an electric current to a temperature above the wafer processing temperature. Preferably, paddle thermocouple 120 is heated to a temperature which is 50-200° C. above the maximum process temperature, and more preferably to a temperature range of 100-200° C. above the maximum process temperature.

Cyclic and independent heating of paddle thermocouple 120 causes cracking of the deposited layers due to differences in coefficient of thermal expansion between the materials of paddle thermocouple 120 and the deposited layer. The stresses are relieved from the deposited layer when the deposited layer cracks. Paddle thermocouple 120 is allowed to cool down after the heating of paddle thermocouple 120 is complete until paddle thermocouple 120 reaches a temperature equal to reaction chamber 100 again. In accordance with another embodiment of the present invention, the deposited layer may be cracked by cyclic cooling or alternate cooling and heating of paddle thermocouple 120. Cyclic cooling or alternate cooling and heating of paddle thermocouple 120 causes cracking of the deposited layers due to differences in coefficient of thermal expansion between the materials of paddle thermocouple 120 and the deposited layer.

FIG. 2 is a top cross sectional view of the paddle thermocouple 120 in accordance with an embodiment of the present invention.

Paddle thermocouple 120 includes a ceramic tube 202, a plurality of channels 204, a second heater 206 integrated with paddle thermocouple 120, a protective sheath 208 around heater 206 and a deposited layer 210.

Paddle thermocouple 120 has at least one pair of wires (not shown) which form a temperature measuring junction. Ceramic tube 202 comprises plurality of channels 204 which run axially along the length of paddle thermocouple 120. A pair of thermocouple wires is situated inside a pair of adjacent channels 204. Each of the thermocouple wires is situated in a separate channel of the pair of adjacent channels 204. Recesses are provided in the outside of ceramic tube 202 at various heights to open up two adjacent channels 204 to connect the pair of thermocouple wires to form a thermocouple junction. Ceramic tube 202 may be made of Al₂O₃ and more preferably ultra pure Al₂O₃.

Second heater 206 is provided outside ceramic tube 202. Second heater 206 comprises one or more heating wire loops that extend in a direction parallel to the length of paddle thermocouple 120. The one or more heating wire loops of second heater 206 are meant for heating paddle thermocouple 120 and are different from the thermocouple wires described above. In an embodiment of the present invention, the one or more heating wire loops are made of NICROTHAL™ alloy from Kanthal. In an embodiment of the present invention the one or more heating wire loops are wound around ceramic tube 202 from a bottom end to a top end and then from the top end to the bottom end through one of channels 204. In an embodiment of the present invention, two channels 204 may be provided in ceramic tube 202 to accommodate the one or more heating wire loops.

In another embodiment of the present invention, two grooves may be provided in the outer surface of ceramic tube 202 for receiving the one or more heating wire loops. The grooves are preferably provided along the axial direction of ceramic tube 202. In various embodiments of the present invention, the one or more heating wire loops may be wound on a separate tube which is mounted to paddle thermocouple 120 by inserting the separate tube in the grooves of paddle thermocouple 120 or in channels 204.

Hot gases are passed inside reaction chamber 100 for the deposition of a film on the semiconductor wafers. The hot gases deposit on the semiconductor wafers and solidify. However, the hot gases are also deposited on paddle thermocouple 120, present inside reaction chamber 100. The hot gases solidify and form deposited layer 210 on paddle thermocouple 120. Deposited layer 210 formed on paddle thermocouple 120 keeps on increasing in thickness during the deposition process and stresses are developed in the deposited layer.

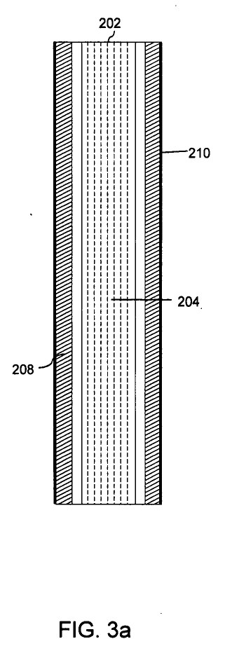

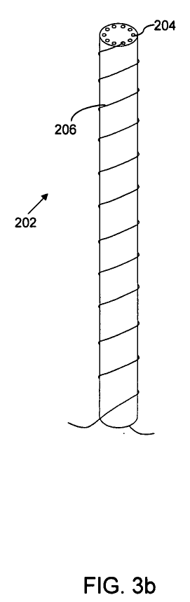

FIG. 3a is a cross-sectional view of the paddle thermocouple taken along line A-A′ of FIG. 2 in accordance with an embodiment of the present invention. Paddle thermocouple 120 comprises ceramic tube 202, plurality of channels 204, protective sheath 208 and deposited layer 210.

Plurality of channels 204 run axially along the length of paddle thermocouple 120 and are used for accommodating thermocouple wires and the one or more heating wire loops of second heater 206 (shown in FIG. 3b).

FIG. 3b is a perspective view of a ceramic tube 202 in accordance with an embodiment of the present invention. In accordance with an embodiment of the present invention, the one or more heating wire loops are wound around ceramic tube 202. In accordance with another embodiment of the present invention, the one heating wire may be wound around the outer surface of ceramic tube 202 and the other heating wire may be situated in one of the plurality of channels 204.

In accordance with another embodiment of the present invention, a ceramic tube of smaller diameter may be used for winding the one or more heating wire loops outside of ceramic tube 202, keeping the inner and outer diameter of protective sheath 208 the same.

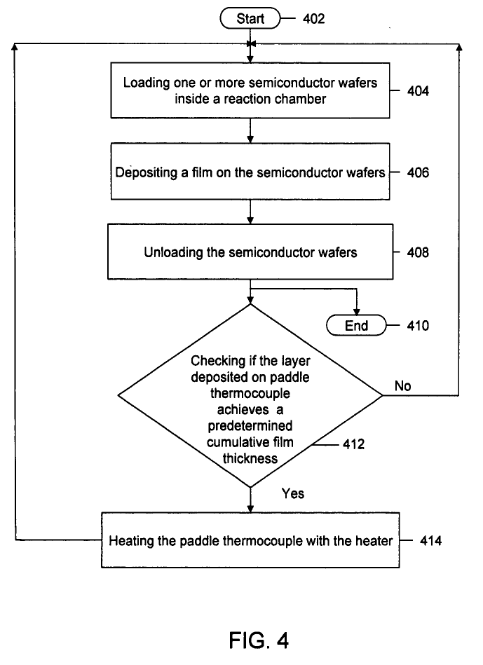

FIG. 4 is a flowchart describing a method for processing semiconductor wafers in accordance with an embodiment of the present invention.

The process starts at step 402. At step 404, the one or more semiconductor wafers are loaded inside reaction chamber 100. At step 406, a film is deposited on the semiconductor wafers. Hot gases are passed inside reaction chamber 100 to deposit a film on the one or more semiconductor wafers.

At step 408, the semiconductor wafers are unloaded from reaction chamber 100 after a film is deposited on the one or more semiconductor wafers. The deposition process ends at step 410 when the deposition of film on the one or more wafers is complete. In the semiconductor industry, multiple wafers are processed continuously and therefore, wafer processing is resumed at step 402.

During the deposition of films on the one or more semiconductor wafers, hot gases also get deposited on the functional elements such as on paddle thermocouple 120 and form deposited layer 210. The thickness of deposited layer 210 formed on paddle thermocouple 120 keeps on increasing during the deposition process, and stresses are developed in the deposited layer. The intensity of the stresses increases with the increase in the thickness of deposited layer 210.

The cumulative thickness of deposited layer 210 on paddle thermocouple 120 is compared at step 412 with a predefined thickness to determine if deposited layer 210 has achieved a predefined thickness. The cumulative thickness is determined by measuring the thicknesses of films on semiconductor wafers in consecutive runs since the last thermocouple sheath replacement or thermocouple heating cycle. If deposited layer 210 on paddle thermocouple 120 has not achieved the predefined thickness, the wafer processing process is resumed from step 402. However, if deposited layer 210 on paddle thermocouple 120 has achieved the predefined thickness, the reaction chamber is put in a stand-by mode and paddle thermocouple 120 is heated to a predefined temperature at step 414. The predefined temperature is determined based upon the material and dimensions of paddle thermocouple 120, and the material of the deposited layer. The predefined temperature is higher than the wafer processing temperature. Preferably, paddle thermocouple 120 is heated to a temperature which is 50-200° C. above the maximum process temperature, and more preferably to a temperature range of 100-200° C. above the maximum process temperature.

In accordance with an embodiment of the present invention, paddle thermocouple 120 is integrated with a heater. The heater is used to heat the paddle thermocouple 120 independent of the reaction chamber. The heater comprises one or more wire loops and has been described in detail in conjunction with FIGS. 2 and 3.

Cyclic and independent heating of paddle thermocouple 120 causes cracking of deposited layer 210 due to differences in coefficient of thermal expansion between the materials of the sheath 208 of paddle thermocouple 120 and deposited layer 210. The stresses from deposited layer 210 are relieved when the deposited layer cracks. After the heating of the paddle thermocouple is complete, paddle thermocouple 120 is allowed to cool down until the paddle thermocouple 120 reaches the temperature equal to the reaction chamber again. In accordance with another embodiment of the present invention, deposited layer 210 may be cracked by cyclic cooling or alternate cooling and heating of the paddle thermocouple 120.

The system and method described above relieves the stresses from the layer that gets deposited on the surface of the paddle thermocouple and therefore, prevents flake off of the layer. This enables effective processing of semiconductor wafers and increase the lifetime of the paddle thermocouple. The heating of the paddle thermocouple is conducted independent of the heating of the reaction chamber, and causes cracking of the deposited layer only, and thus avoids any damage of the thermocouple or other fragile parts inside the reaction chamber. This increases the life-time of the other fragile parts because these fragile parts are not heated along with the thermocouple. Furthermore, regular examination and cracking of the deposited layer avoids abrupt shutting down of the reaction chamber due to uncontrolled breakage of the thermocouple and other fragile parts of the reaction chamber. This increases efficiency of the reaction chamber.

The present invention has been described in connection with the paddle thermocouple for the purpose of illustration and description purpose only. However, it is not intended to limit the scope of the present invention as the present invention may be embodied using other functional elements such as quartz injectors and the like.

While various embodiments of the present invention have been illustrated and described, it will be clear that the present invention is not limited to these embodiments only. Numerous modifications, changes, variations, substitutions and equivalents will be apparent to those skilled in the art, without departing from the spirit and scope of the present invention, as described in the claims.

What is claimed is:

1. A component for use inside a reaction chamber of a thermal film deposition apparatus, the thermal film deposition apparatus comprising a first heater for heating the reaction chamber to a wafer processing temperature, the component comprising:
i. a functional element, the functional element being adapted for use in the thermal film deposition apparatus, wherein a surface of the functional element is exposed to the film deposition processing conditions; and
ii. a second heater, the second heater being included with the functional element to heat the component.

2. The component according to claim 1, wherein the functional element is a thermocouple.

3. The component according to claim 2, wherein the thermocouple comprises:
i. a ceramic tube, the ceramic tube being provided with channels for accommodating at least one pair of thermocouple wires forming a thermocouple junction; and
ii. a protective sheath, the protective sheath being provided to protect and isolate the ceramic tube and the at least one pair of thermocouple wires from the film deposition processing conditions.

4. The component according to claim 1, wherein the second heater extends axially along a length of the component.

5. The component according to claim 1, wherein the second heater comprises one or more wire loops.

6. The component according to claim 1, wherein the second heater is configured to heat the component to a predefined temperature, the predefined temperature being 50-200° C. higher than the wafer processing temperature.

7. A device for measuring temperature inside a reaction chamber, the device comprising at least one pair of wires, the at least one pair of wires forming a temperature measuring junction, the device comprising:
i. a ceramic tube, the ceramic tube comprising a plurality of channels running along an axial dimension of the ceramic tube, the plurality of channels being configured to accommodate one or more of the at least one pair of wires; and
ii. a heater, the heater extending along the axial dimension, the heater integrated with the device and configured to heat the device to a predefined temperature.

8. The device according to claim 7, wherein the heater comprises one or more heating elements, the one or more heating elements running parallel to the length of the device.

9. The device according to claim 8, wherein the one or more heating elements are one or more wire loops.

10. The device according to claim 7, wherein the device comprises a protective sheath, the protective sheath being provided for protecting and isolating the ceramic tube and the at least one pair of wires from the film deposition processing conditions.

11. A method for preventing flake-off of a layer from a surface of a component, the component being disposed inside a reaction chamber of a thermal film deposition apparatus, the method comprising the steps:
i. loading one or more wafers inside the reaction chamber;
ii. depositing a film on the one or more wafers at a wafer processing temperature;
iii. unloading the one or more wafers; and
iv. heating the component to a predefined temperature independent of the processing temperature when the layer achieves a predetermined cumulative film thickness, the component being provided with one or more heaters.

12. The method according to claim 11, wherein the predefined temperature is 50-200° C. higher than the wafer processing temperature.

13. The method according to claim 11, wherein the reaction chamber is maintained at a temperature equal to the wafer processing temperature during heating of the component.

14. The method according to claim 11, wherein the reaction chamber is maintained at a temperature lower than the wafer processing temperature during heating of the component.

15. A method for processing one or more wafers inside a reaction chamber of a thermal film deposition apparatus, the thermal film deposition apparatus comprising a component disposed inside the reaction chamber, a layer being deposited on to a surface of the component, the method comprising the steps:
i. loading the one or more wafers inside the reaction chamber;
ii. depositing a film on the one or more wafers at a wafer processing temperature;
iii. unloading the one or more wafers from the reaction chamber; and
iv. heating the component to a predefined temperature independent of the wafer processing temperature when the layer achieves a predetermined cumulative film thickness, the component being provided with one or more heaters.

16. The method according to claim 15, wherein the predefined temperature is 50-200° C. higher than the wafer processing temperature.
